(19) United States
(12) Patent Application Publication
(10) Pub. No.: US 2010/0248396 A1
(43) Pub. Date: Sep. 30, 2010

(54) HEAT TREATMENT APPARATUS AND CONTROL METHOD THEREFOR

(75) Inventor: Kei Ogose, Nirasaki (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/814,547

(22) Filed: Jun. 14, 2010

Related U.S. Application Data
(63) Continuation of application No. PCT/JP2008/072328, filed on Dec. 9, 2008.

(30) Foreign Application Priority Data
Dec. 15, 2007 (JP) 2007-324097

(51) Int. Cl. H01L 21/477; H01L 21/46

(52) U.S. Cl. 438/5; 237/2 R; 118/666; 257/E21.497; 257/E21.482

(57) ABSTRACT

A heat treatment apparatus includes a processing chamber having a gate valve at a sidewall and a cover at a ceiling via a sealing member; a gate valve heating unit provided at the gate valve; a processing chamber heating unit provided at a sidewall of the processing chamber; and a temperature controller that controls a set temperature for the sidewall of the processing chamber adjacent to the gate valve to be lower than a set temperature for an opposite sidewall of the processing chamber from the gate valve by controlling the processing chamber heating unit. The two set temperatures are set to be higher than a sublimation temperature of a reaction by-product, or higher than a condensation temperature of the gas, and the two set temperatures are also set to be lower than a temperature at which an amount of a gas permeating the sealing member increases.

### CROSS-REFERENCE TO RELATED APPLICATION

This application is a Continuation of International Application No. PCT/JP2008/072328 filed on Dec. 9, 2008, which claims the benefits of Japanese Patent Application No. 2007-324097 filed on Dec. 15, 2007. The entire disclosure of the prior application is incorporated herein by reference in its entirety.

### FIELD OF THE INVENTION

The present disclosure relates to a heat treatment apparatus for performing a heat treatment such as a film forming process on a processing target object such as a semiconductor wafer; and also relates to a control method for the heat treatment apparatus.

### BACKGROUND OF THE INVENTION

In general, various processes, such as a film forming process, an etching process, an oxidation process, a diffusion process and a natural oxide film removing process, are repetitively performed on a semiconductor wafer such as a silicon substrate so as to manufacture a semiconductor integrated circuit or the like. In implementing such various kinds of processes, it is very important for the improvement of a product yield to uniformly perform the processes on the entire surface of the wafer with high reproducibility. Known as a processing apparatus configured to perform such a process is a single-wafer processing apparatus as disclosed in, e.g., Japanese Patent Laid-open Publication No. 2004-047644 or Japanese Patent Laid-open Publication No. 2007-141895.

Now, an example of a conventional single-wafer processing apparatus will be explained. FIG. 6 is a schematic cross sectional view of the conventional single-wafer processing apparatus. As illustrated in FIG. 6, a processing apparatus 2 includes a processing chamber 4 made of, e.g., an aluminum alloy. The inside of the processing chamber 4 forms a processing space S of a substantially circular cross sectional shape. A mounting table 6 configured to mount thereon a semiconductor wafer W as a processing target object is installed within the processing chamber 4. Embedded in the mounting table 6 is a wafer heater 8 configured to heat the wafer W.

An exhaust port 10 is provided in a bottom portion of the processing chamber 4. An atmosphere within the chamber can be exhausted via the exhaust port 10 by a vacuum exhaust system including a non-illustrated vacuum pump. With this configuration, a pressure of the atmosphere within the chamber can be adjusted.

A loading/unloading port 12 through which the wafer W is loaded or unloaded is provided in a sidewall of the processing chamber 4. A gate valve 14 configured to be opened and closed during the loading and unloading of the wafer W is airtightly installed at the loading/unloading port 12 via a sealing member 16. A vacuum transfer chamber 18 having a transfer arm for the wafer W is connected to an opposing side of the gate valve 14 from the loading/unloading port 12. Further, a gate valve heater 20 serving to heat and maintain the gate valve 14 at a preset temperature is provided at the gate valve 14.

A ceiling of the processing chamber 4 is configured as a cover 22 horizontally separated from a chamber main body. A shower head 24 is installed at the cover 22. Various kinds of gases necessary for a heat treatment are introduced into the processing space S through a plurality of gas discharge holes 26 provided in a bottom surface of the shower head 24. Further, a head heater 28 serving to heat and maintain the shower head 24 at a certain temperature is provided in the shower head 24.

The cover 22 and the processing chamber 4 may have substantially quadrangular appearances. A hinge 30 is installed at one side of the cover 22. Accordingly, during the maintenance of the shower head 24, the cover 22 can be unfolded from the processing chamber 4, so that the inside of the chamber can be opened. Further, a sealing member 32 such as an O-ring is installed at a joint portion between the cover 22 and the chamber main body along a circumferential direction of the processing chamber 4. Furthermore, one or more chamber heaters 34 serving to heat a sidewall of the processing chamber 4 are provided in the sidewall of the processing chamber 4. For example, four chamber heaters 34 can be provided in four corners of the quadrangular processing chamber 4.

When a heat treatment, for example, a film forming process, is performed by the processing apparatus configured as described above, a film forming gas is discharged from the shower head 24, and the inside of the processing chamber 4 is maintained at a preset processing pressure. Simultaneously, the wafer W on the mounting table 6 is maintained at a preset temperature, and the film forming process is performed on the wafer W. At this time, a reaction by-product is highly likely to be adhered to a surface of the shower head 24 or a sidewall surface of the processing chamber 4. Accordingly, in order to prevent adhesion of the reaction by-product, the shower head 24, the gate valve 14 and the sidewall of the processing chamber 4 need be heated by the head heater 28, the gate valve heater 20 and the chamber heaters 34, respectively, and, thus, a so-called hot wall state is created.

In the conventional processing chamber, these heating temperatures are not particularly limited and are considered sufficient only if they are equal to or higher than a sublimation temperature of the reaction by-product. For example, when a TiN film is formed through the heat treatment, ammonium chloride is generated as a reaction by-product. Since a sublimation temperature of the ammonium chloride is about 160° C., the sidewall of the processing chamber 4 needs be heated at a temperature equal to or higher than such a sublimation temperature.

When the film forming process is performed by the conventional film forming apparatus as described above, sheet resistances of thin films formed on a wafer surface have high non-uniformity even if a heating temperature for the wafer W is precisely controlled, resulting in deterioration of intra-surface uniformity.

### BRIEF SUMMARY OF THE INVENTION

In view of the foregoing, the present disclosure has been conceived to solve the mentioned problems effectively. The present disclosure provides a heat treatment apparatus capable of improving intra-surface uniformity of a heat treatment such as a film forming process performed on a processing target object; and also provides a method for controlling the heat treatment apparatus.

The present inventor has conducted many researches to find out a reason why the intra-surface uniformity of the sheet resistances of the formed TiN films is poor in spite of precise uniform control of the intra-surface temperature of the semiconductor wafer. As a result, the present inventor has found out that a gas may permeate a sealing member depending on a temperature of the processing chamber's sidewall opposite to where the gate valve is installed, and the sheet resistances in the vicinity of that sidewall may vary by the gas permeation. The present disclosure is derived based on this finding.

In accordance with a first aspect of the present disclosure, there is provided a heat treatment apparatus including a processing chamber having a gate valve at a sidewall and a cover at a ceiling via a sealing member, the gate valve being configured to be opened and closed so as to load and unload a processing target object and the cover being configured to be opened and closed; a mounting table provided within the processing chamber and configured to mount the processing target object; a gas introduction unit configured to introduce a gas into the processing chamber; an exhaust unit configured to exhaust an atmosphere gas in the processing chamber; a processing target object heating unit configured to heat the processing target object; a gate valve heating unit provided at the gate valve; a processing chamber heating unit provided at a sidewall of the processing chamber; and a temperature controller that controls a set temperature for the sidewall of the processing chamber adjacent to the gate valve to be lower than a set temperature for an opposite sidewall of the processing chamber from the gate valve by way of controlling the processing chamber heating unit. Here, the two set temperatures are set to be equal to or higher than a sublimation temperature of a reaction by-product generated by a heat treatment performed on the processing target object, or equal to or higher than a condensation temperature of the gas, and the two set temperatures are also set to be equal to or lower than a temperature at which an amount of a gas permeating the sealing member increases.

In accordance with the present disclosure, the set temperature for the opposite sidewall of the processing chamber from the gate valve is set to be higher than the set temperature for the sidewall of the processing chamber adjacent to the gate valve, and these set temperatures are also set to be equal to or lower than a temperature at which an amount of a gas permeating the sealing member increases. Accordingly, the amount of the gas permeating the sealing member into the processing chamber can be reduced greatly. As a result, when a heat treatment such as a film forming process is performed on the processing target object, intra-surface uniformity of the heat treatment can be improved.

Desirably, the processing chamber heating unit may include a pair of gate valve side heaters provided at the sidewall of the processing chamber adjacent to the gate valve and arranged apart from each other at a preset distance; a pair of outer side heaters provided at the opposite sidewall of the processing chamber from the gate valve and arranged apart from each other at a preset distance.

Desirably, a gate valve side temperature measuring unit may be provided in the vicinity of the gate valve side heaters to measure a temperature of the gate valve side heaters, and an outer side temperature measuring unit may be provided in the vicinity of the outer side heaters to measure a temperature of the outer side heaters.

Desirably, a difference between the two set temperatures may be in a range of about 5° C. to about 30° C.

By way of example, the heat treatment may be a film forming process for forming a thin film, and the two set temperatures may be determined to allow an intra-surface difference of sheet resistances of the thin film to be equal to or smaller than about 20% of an average value of the sheet resistances.

By way of example, the sealing member may be made of a fluoroelastomer-based material.

In accordance with a second aspect of the present disclosure, there is provided a method for controlling a heat treatment apparatus including a processing chamber having a gate valve at a sidewall and a cover at a ceiling via a sealing member, the gate valve being configured to be opened and closed so as to load and unload a processing target object and the cover being configured to be opened and closed; a mounting table installed within the processing chamber and configured to mount the processing target object; a gas introduction unit configured to introduce a gas into the processing chamber; an exhaust unit configured to exhaust an atmosphere gas in the processing chamber; a processing target object heating unit configured to heat the processing target object; a gate valve heating unit provided at the gate valve; a processing chamber heating unit provided at a sidewall of the processing chamber; and a temperature controller that controls the processing chamber heating unit. The method for controlling a heat treatment apparatus includes: increasing a set temperature for the sidewall of the processing chamber adjacent to the gate valve lower than a set temperature for an opposite sidewall of the processing chamber from the gate valve by using the temperature controller. Here, the two set temperatures are set to be equal to or higher than a sublimation temperature of a reaction by-product generated by a heat treatment performed on the processing target object, or equal to or higher than a condensation temperature of the gas, and the two set temperatures are also set to be equal to or lower than a temperature at which an amount of a gas permeating the sealing member increases.

Desirably, a difference between the two set temperatures may be in a range of about 5° C. to about 30° C.

Further, the heat treatment may be, e.g., a film forming process for forming a thin film, and the two set temperatures may be determined to allow an intra-surface difference of sheet resistances of the thin film to be equal to or smaller than about 20% of an average value of the sheet resistances.

In accordance with a third aspect of the present disclosure, there is provided a storage medium storing therein a computer program for executing the above-mentioned method for controlling a heat treatment apparatus.

### BRIEF DESCRIPTION OF THE DRAWINGS

The disclosure may best be understood by reference to the following description taken in conjunction with the following figures:

FIG. 1 is a schematic longitudinal cross sectional view of a heat treatment apparatus in accordance with an embodiment of the present disclosure;

FIG. 2 is a transversal cross sectional view of the heat treatment apparatus of FIG. 1;

FIG. 3 is a circuit diagram for describing a connection state of a processing chamber heating unit of FIG. 1;

FIG. 4 is a graph showing a variation of a resistance ratio of a thin film along a diametrical direction of a semiconductor wafer;

FIG. 5 is a graph showing sheet resistance states of TiN films on semiconductor wafers formed by a conventional method and a present disclosure method; and

FIG. 6 is a schematic longitudinal cross sectional view illustrating an example of a conventional single-wafer processing apparatus.

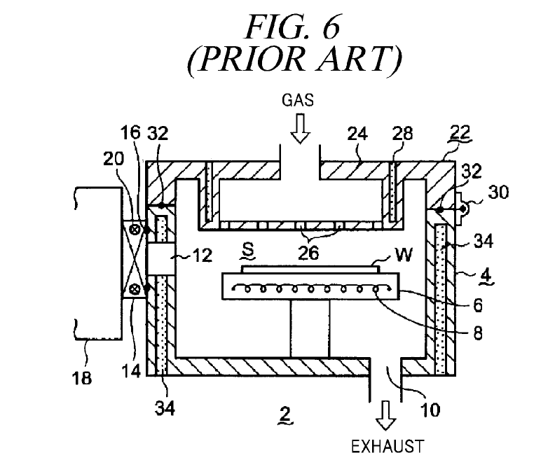

### DETAILED DESCRIPTION OF THE INVENTION

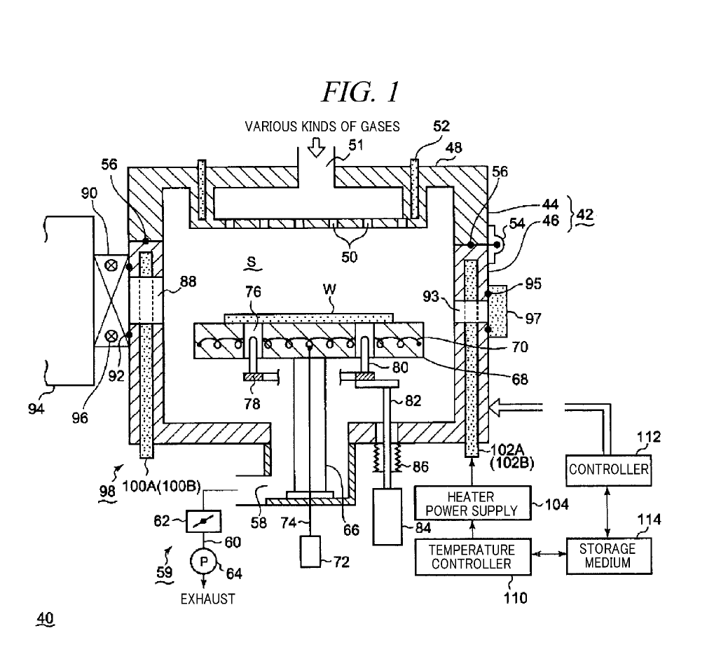

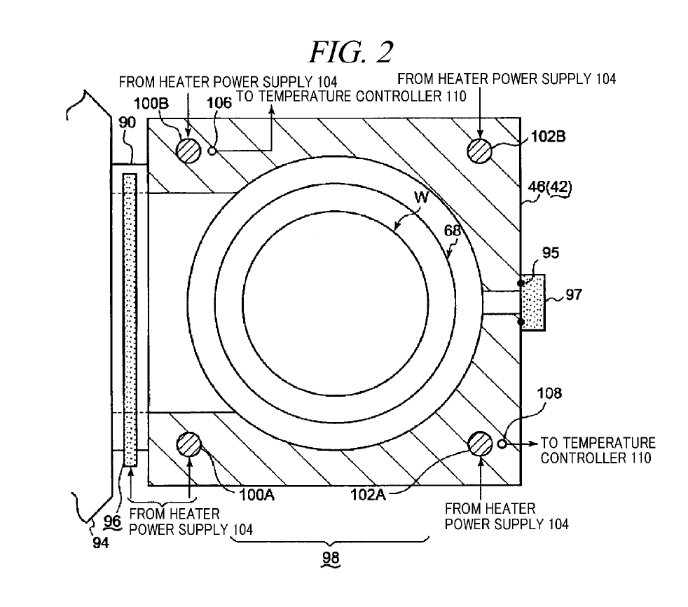

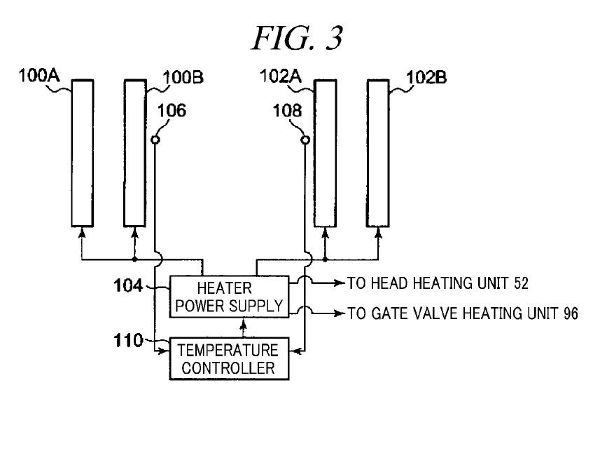

Hereinafter, a configuration of a heat treatment apparatus in accordance with an embodiment of the present disclosure will be described with reference to FIGS. 1 to 3. FIG. 1 is a schematic longitudinal cross sectional view of a heat treatment apparatus 40 in accordance with an embodiment of the present disclosure. FIG. 2 sets forth a transversal cross sectional view of the heat treatment apparatus of FIG. 1, and FIG. 3 is a circuit diagram for describing a connection state of a processing chamber heating unit of FIG. 1.

As illustrated, the heat treatment apparatus 40 includes a processing chamber 42 of which inside is formed in a substantially circular cross sectional shape and made of, e.g., aluminum or an aluminum alloy. The processing chamber 42 has an appearance of a substantially quadrangular cross sectional shape.

The processing chamber 42 includes a cover 44 and a chamber main body 46 below the cover 44, and the cover 44 is horizontally separated from the chamber main body 46 at a ceiling portion of the processing chamber 42. The cover 44 is provided with a shower head 48 configured as a gas introduction unit. A plurality of gas discharge holes 50 is provided in a bottom surface of the shower head 48, and various kinds of processing gases are introduced into a processing space S within the processing chamber 42 through the gas discharge holes 50. Further, provided in a top portion of the shower head 48 are one or more gas inlet ports 51 through which the various kinds of processing gases are supplied while their flow rates are controlled independently.

Depending on a process involved, a so-called pre-mix type structure in which plural gases are mixed within the shower head 24 may be adopted. Alternatively, there may be adopted a so-called post-mix type structure in which the inside of the shower head is divided into a plurality of separate spaces, and plural gases are discharged into and then mixed in the processing space S after they pass through the respective spaces.

A head heating unit 52 such as a bar-shaped cartridge heater is embedded in the shower head 48, so that the shower head 48 can be heated to a preset temperature.

One side of the cover 44 is coupled to a top portion of the chamber main body 46 via a hinge 54. Accordingly, the cover 44 can be unfolded by 180 degrees during the maintenance of the apparatus. Further, a sealing member 56 such as an O-ring is provided between a lower end of the cover 44 and an upper end of the chamber main body 46 along a circumferential direction of the chamber main body 46, so that the cover 44 and the chamber main body 46 can be hermetically sealed. A fluoroelastomer-based material, such as Viton (registered trademark), Karlez (registered trademark) or Armor (registered trademark), may be used as the sealing member 56.

Further, a central bottom portion of the processing chamber 42 is formed in a downwardly recessed shape. An exhaust port 58 is provided at a side surface of the recess-shaped portion. An exhaust unit 59 is coupled to the exhaust port 58. The exhaust unit 59 has an exhaust path 60 coupled to the exhaust port 58. A pressure control valve 62, a vacuum pump 64 and the like are installed on the exhaust path 60 in sequence. With this configuration, the inside of the processing chamber 42 can be evacuated, so that a pressure therein can be adjusted. Further, a mounting table 68 configured to mount thereon a semiconductor wafer W as a processing target object is installed at a bottom portion of the processing chamber 42 via a supporting column 66.

The mounting table 68 is made of, e.g., a ceramic material such as aluminum nitride (AlN). As a heating unit for the processing target object, a heater 70 including a resistor such as molybdenum or tungsten wire is embedded within the AlN-made mounting table 68 in an array of a preset pattern. The heater 70 is coupled to a heater power supply 72 via a wire 74. With this configuration, a power is fed to the heater 70 when necessary, and the wafer W can be controlled to a preset temperature.

The mounting table 68 is provided with three pin holes 76 vertically formed through the mounting table 68 (only two of them are shown in FIG. 1). Elevating pins 80 made of, e.g., quartz and having lower ends commonly supported by an arc-shaped connection ring 78 are inserted through the respective pin holes 76 in a movable state. The connection ring 78 is held on an upper end of an elevating rod 82 configured to move up and down through a bottom portion of the chamber. A lower end of the elevating rod 82 is coupled to an actuator 84. With this configuration, each elevating pin 80 can be protruded/retracted from/into an upper end of each pin hole 76 to transfer the wafer W. Further, an expansible/contractible bellows 86 is installed at the chamber bottom portion penetrated by the elevating rod 82. Accordingly, the elevating rod 82 can be moved up and down while the inside of the processing chamber 42 is kept airtight.

A loading/unloading port 88 through which the wafer W is loaded and unloaded is provided at one side of a sidewall of the processing chamber 42. A gate valve 90 configured to be opened and closed during the loading and unloading of the wafer W is airtightly installed at the loading/unloading port 88 via a sealing member 92 such as an O-ring. An evacuable transfer chamber 94 equipped with a transfer arm for the wafer W is connected to an opposing side of the gate valve 90 from the processing chamber 42. Further, a gate valve heating unit 96 such as a cartridge heater is provided at the gate valve 90 so as to heat and maintain the gate valve 90 at a preset temperature.

An observation hole 93 is formed in an opposing side of the sidewall from where the gate valve 90 is provided, and an observation window 97 made of, e.g., quartz is airtightly provided outside the observation hole 93 via a sealing member 95 such as an O-ring.

Further, a chamber heating unit 98 is provided in the (almost entire) sidewall of the processing chamber 42 so as to create a hot wall state by heating the sidewall of the processing chamber 42. To elaborate, as illustrated in FIGS. 2 and 3, the chamber heating unit 98 includes at least a pair of gate valve side heaters 100A and 100B and a pair of outer side heaters 102A and 102B. The gate valve side heaters 100A and 100B are provided in the processing chamber 42's sidewall adjacent to the gate valve 90 along a height direction of the sidewall while they are spaced apart from each other at a certain distance. Meanwhile, the outer side heaters 102A and 102B are provided in the processing chamber 42's sidewall opposite from the gate valve 90 along a height direction of the sidewall while they are also spaced apart from each other at a certain distance. In the shown example, the heaters 100A, 100B, 102A and 102B are respectively positioned at four corners of the processing chamber 42 having the substantially quadrangular sectional shape when viewed from the top thereof.

The respective heaters 100A to 102B such as bar-shaped cartridge heaters are embedded within the sidewalls of the processing chamber. The pair of gate valve side heaters 100A and 100B is coupled to a heater power supply 104 and is controlled as a single unit (see FIG. 3). Further, the pair of outer side heaters 102A and 102B is also coupled to the heater power supply 104 and controlled as a single unit (see FIG. 3).

Moreover, a gate valve side temperature measuring unit 106 such as a thermocouple is provided in the vicinity of one of the two gate valve side heaters 100A and 100B, e.g., the heater 100B. The gate valve side temperature measuring unit 106 measures a temperature of the vicinity of the heater 100B. Likewise, an outer side temperature measuring unit 108 such as a thermocouple is provided in the vicinity of one of the two outer side heaters 102A and 102B, e.g., the heater 102A. The outer side temperature measuring unit 108 measures a temperature in the vicinity of the heater 102A.

Outputs of the two temperature measuring units 106 and 108 are inputted to a temperature controller 110 such as a computer (see FIG. 3). The temperature controller 110 controls the pair of gate valve side heaters 100A and 100B and the pair of outer side heaters 102A and 102B independently through the heater power supply 104 (see FIG. 3). Further, although not shown, the heater power supply 104 also feeds a power to the head heating unit 52 or the gate valve heating unit 96, and thus controls their temperatures.

The entire apparatus as described above is controlled by a controller 112 such as a computer. Specifically, a start and a stop of the supply of each gas, a flow rate of each gas, a temperature of the wafer W, a pressure within the processing chamber 42, and the like are all controlled by the controller 112. The temperature controller 110 is also controlled by the controller 112. Further, a computer-readable program necessary for the control or a process recipe specifying set values to be used as control targets is stored in a storage medium 114. A program to be used in the temperature controller 110 may also be stored in this storage medium 114. The storage medium 114 may be, e.g., a flexible disk, a CD (Compact Disk), a CD-ROM, a hard disk, a flash memory, a DVD, or the like.

Now, a method for using (controlling) the processing apparatus configured as described above will be explained for a film forming process as an example heat treatment. Here, formation of a TiN thin film by a CVD (Chemical Vapor Deposition) process will be illustrated.

In this film forming process, the gate valve 90 in the sidewall of the processing chamber 42 is first opened, and an unprocessed semiconductor wafer W such as a silicon substrate is loaded into the processing chamber 42 from the transfer chamber 94 through the loading/unloading port 88 by a non-illustrated transfer arm. The wafer W is transferred onto the elevating pins 80, and as the elevating pins 80 are lowered, the wafer W is mounted on the mounting table 68.

Subsequently, the gate valve 90 is closed, and an input power to the heater 70 of the mounting table 68 is increased, so that a temperature of the mounting table 68 which was in preheating state is raised to and maintained at a processing temperature. Here, a processing temperature is, e.g., about 550° C.

In this step, the shower head 48 has been previously heated by the head heating unit 52 and already maintained at a preset temperature. Further, the gate valve 90 has also been previously heated by the gate valve heating unit 96 and already maintained at a preset temperature. Likewise, the sidewalls of the processing chamber 42 have also been previously heated by the gate valve side heaters 100A and 100B and the outer side heaters 102A and 102B of the chamber heating unit 98, and already maintained at preset temperatures. In this way, a so-called hot wall state is created, thereby preventing adhesion of reaction by-products.

In this state, various kinds of film forming gases, e.g., a TiCl₄ gas and a NH₃ gas are fed into the processing space S while their flow rates are controlled, and an atmosphere within the processing chamber 42 is exhausted by the exhaust unit 59 to maintain a preset processing pressure, so that a film forming process is performed by CVD.

As stated above, a thin film of TiN is formed on the wafer W through this film forming process. During the formation of the TiN film, ammonium chloride (NH₄Cl) is generated as a reaction by-product as a result of a reaction between the TiCl₄ gas and the NH₃ gas.

A temperature control for the sidewalls of the processing chamber 42 is performed as follows. A temperature of the processing chamber 42's sidewall adjacent to the gate valve 90 is measured by the gate valve side temperature measuring unit 106 (see FIG. 2), and based on this measurement result and a control target temperature, the temperature controller 110 controls a power fed to the pair of gate valve side heaters 100A and 100B via the heater power supply 104 so as to allow the measurement result to be close to the control target temperature. Meanwhile, a temperature of the processing chamber 42's opposite sidewall (adjacent to the observation window 97) from the gate valve 90 is measured by the outer side temperature measuring unit 108 (see FIG. 2), and based on this measurement result and a control target temperature, the temperature controller 110 controls a power fed to the pair of outer side heaters 102A and 102B via the heater power supply 104 so as to allow the measurement result to be close to the control target temperature.

In a conventional processing apparatus, the temperature controller 110 controlled the temperatures of the chamber sidewall adjacent to the gate valve 90 and the chamber sidewall opposite from the gate valve 90 to a same set temperature equal to or higher than a sublimation temperature of a reaction by-product. Such a control was based on a conception that it would be enough to heat the sidewall surfaces to a temperature equal to or higher than the sublimation temperature of the reaction by-product (about 160° C. in case of ammonium chloride). Further, an upper limit of the set temperature was not particularly limited. For example, the set temperature was about 170° C.

In the conventional processing apparatus, however, an increase of a sheet resistance at a periphery portion of the wafer W was greater than an increase of a sheet resistance at a central portion thereof. That is, due to the high non-uniformity of sheet resistances, intra-surface uniformity was low. According to analysis of the present inventor for this problem, the following facts have been found out: the temperature of the sealing member 56 between the cover 44 and the chamber main body 46 was increased excessively; as a result, gas permeability of the sealing member 56 was increased; as a result, an amount of air (gas) permeating the sealing member 56 into the processing space S in a depressurized state was increased; and, thus, oxygen components in the air oxidized thin films on the wafer W, resulting in an increase of a sheet resistance.

Further, in the processing chamber 42, since the gate valve 90 itself is also heated, the chamber sidewall adjacent to the gate valve 90 is heated by heat received from the gate valve 90 as well as by heat generated from the gate valve side heaters 100A and 100B. Accordingly, it is expected that an actual temperature of the chamber sidewall adjacent to the gate valve 90 tends to be higher than the set temperature.

In contrast, since the chamber sidewall (adjacent to the observation window 97) opposite from the gate valve 90 is just exposed to clean air, it receives heat only from the outer side heaters 102A and 102B. Accordingly, it is expected that an actual temperature of this chamber sidewall tend to be substantially equal to or slightly lower than the set temperature.

Therefore, in the present embodiment, the temperature controller 110 controls a set temperature of the chamber sidewall adjacent to the gate valve 90 to be lower than a set temperature of the chamber sidewall opposite from the gate valve 90. Further, the set temperatures are set to be equal to or higher than the sublimation temperature of the reaction by-product generated by the film forming process. Furthermore, the set temperatures are set to be lower than a temperature that increases the gas permeating the sealing member 56.

That is, all the sidewalls of the processing chamber are heated to the respective temperatures equal to or higher than the sublimation temperature of the reaction by-product (here, ammonium chloride) while maintained (controlled) below the temperature at which the permeation gas permeating the sealing member 56 increases. Further, in such a temperature control, the set temperature of the opposite chamber sidewall from the gate valve 90 is set to be slightly higher than the set temperature of the chamber sidewall adjacent to the gate valve 90 that receives extra heat from the gate valve 90 by thermal conduction. Accordingly, the sidewall temperatures of the processing chamber 42 can be uniformed.

To elaborate, the set temperature of the heaters that heats the chamber sidewall adjacent to the gate valve 90, i.e., the gate valve side heaters 100A and 100B is set to be, e.g., about 160° C. Meanwhile, the set temperature of the heaters that heats the opposite chamber sidewall from the gate valve 90, i.e., the outer side heaters 102A and 102B is set to be, e.g., about 175° C., 15° C. higher.

By this setting, the temperatures of the entire sidewalls of the processing chamber 42 can be uniformed to a temperature equal to or higher than the sublimation temperature of the reaction by-product and can be maintained below a temperature that increases the gas permeating the sealing member 56. In general, when a gas permeates a fluoroelastomer-based polymer material, although hole size of the material is not so big for molecule size of the gas, spaces between molecular chains of the material are changed due to thermal motion of the molecular chains. Accordingly, this can create an empty hole allowing a gas to pass therethrough, and the gas adsorbed onto the surface of the material may be separated from the adsorption point and enter the empty hole. As the gas enters and moves through other holes in sequence, a permeation process is completed. Here, as the temperature of the material increases, thermal motion of the molecular chains is also enhanced, and, thus, an amount of the permeation gas is also increased. Thus, in a process showing deterioration of a film quality due to a slight leakage (permeation) of air, it may be desirable to control a temperature of a sealing member-present portion to be as low as possible.

Desirably, a difference between the set temperatures of the gate valve side heaters 100A and 100B and the outer side heaters 102A and 102B may be in the range of about 5° C. to about 30° C. If the difference is smaller than about 5° C., the temperature of the chamber sidewall adjacent to the observation window 97, which shows a tendency of a temperature decrease, may not be sufficiently increased, resulting in deterioration of temperature uniformity of the entire apparatus. Meanwhile, an aluminum material is generally used for the processing chamber 4. Since thermal conductivity of the aluminum itself is high, a temperature difference between the chamber sidewall adjacent to the gate valve 90 and the chamber sidewall adjacent to the observation window 97 may not increase beyond about 30° C. Thus, it may be undesirable to set the difference in the set temperatures to be higher than about 30° C.

Moreover, when thin films are formed by the heat treatment, each set temperature may be set such that intra-surface difference (uniformity) of sheet resistances of the thin films becomes equal to or smaller than about 20% of an average value of the sheet resistances.

In accordance with the present disclosure as described above, the set temperature of the chamber sidewall opposite from the gate valve 90 is set to be higher than the set temperature of the chamber sidewall adjacent to the gate valve 90, and these set temperatures are set to be equal to or higher than the sublimation temperature of the reaction by-product, e.g., ammonium chloride, generated by the heat treatment and lower than the temperature that increases the gas permeating the sealing member 56. Accordingly, the amount of air permeating the sealing member 56 into the processing chamber 42 can be reduced greatly. As a result, when the heat treatment such as the film forming process is performed on the processing target object W, intra-surface uniformity of the heat treatment can be improved.

<Investigation of the Reason for Non-Uniformity in Sheet Resistances>

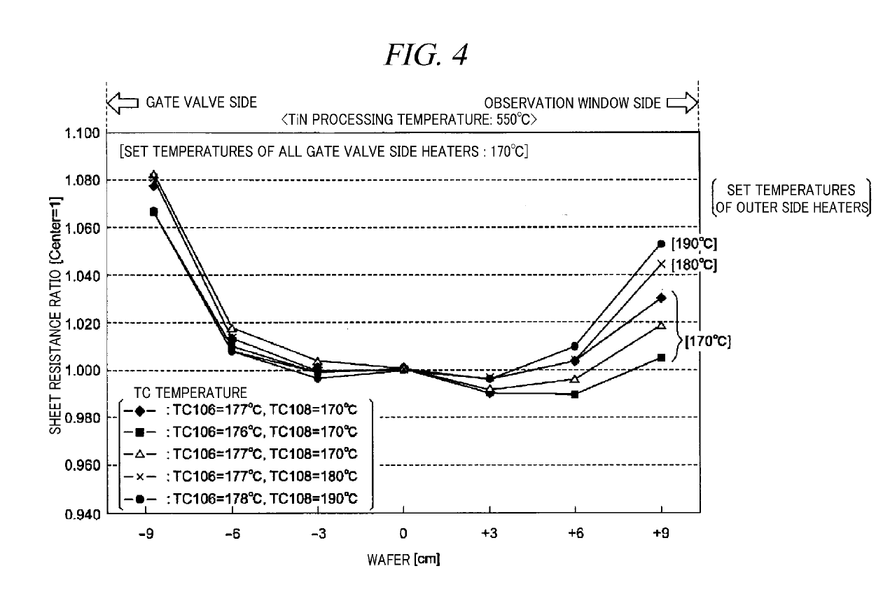

Now, an investigation result of the reason for non-uniformity in sheet resistances of a thin film formed on a surface of a wafer W will be discussed. FIG. 4 is a graph showing resistance ratios of thin films along a diametrical direction of a wafer W. Here, Karlez (registered trademark) was used as the sealing member 56. Further, a TiN film was formed on each of 5 sheets of semiconductor wafers W having a diameter of about 200 mm, and sheet resistances were measured at 7 different points on each wafer W along its diametrical direction. A sheet resistance at a central portion of the wafer W is set to “1” as a reference value, and respective measurement results are expressed as a ratio to the reference value. On the graph, a left part indicates a sheet resistance on a portion adjacent to the gate valve 90, while a right part indicates a sheet resistance on a portion adjacent to the observation window 97. Further, a wafer processing temperature (mounting table temperature) was set to about 550° C. and a processing pressure was set to about 666 Pa.

Moreover, set temperatures of the gate valve side heaters 100A and 100B adjacent to the gate valve (the left part of the graph) were all set to about 170° C. Meanwhile, set temperatures of the outer side heaters 102A and 102B adjacent to the observation window 97 (the right part of the graph) were set to about 170° C. for three sheets of wafers while set to about 180° C. and about 190° C. for the other two wafers, respectively. Further, TC temperatures on the graph are actual measurement values obtained by the gate valve side temperature measuring unit 106 and the outer side temperature measuring unit 108 such as thermocouples.

As can be clearly seen from the graph, although temperatures of the wafers W are maintained substantially uniform at about 550° C. across their entire surfaces, sheet resistances at periphery portions of the wafers W are found to increase in all examples. The reason for this is supposed as discussed above. That is, if the temperature of the sealing member 56 increases up to 170° C. or more, the permeability of the sealing member 56 would increase rapidly, so that the amount of external air permeating the sealing member 56 also increases. As a result, oxygen in the air would oxidize TiN film on the periphery portions of the wafers W, increasing the sheet resistances thereat. Especially, if the set temperatures of the outer side heaters 102A and 102B adjacent to the observation window 97 are increased to about 180° C. and to about 190° C., the sheet resistances are found to increase greatly, and such a rise in temperature is found to cause a rapid increase of the gas permeability of the sealing member 56, resulting in many undesirable results.

Moreover, although the set temperature of the gate valve side heaters 100A and 100B is about 170° C., their actual temperatures are found to range from about 176° C. to about 178° C., much higher than the set temperature. Such a higher temperature is deemed to be caused due to a great amount of heat transfer from the heated gate valve 90 by thermal conduction. In such a case, since the temperature of the processing chamber 42's gate valve side is very high, the permeability of the sealing member 56 increases as described above, undesirably resulting in increase of the sheet resistances up to about 1.06 to about 1.08. That is, the temperature of 170° C. is found to be too high for the set temperature of the gate valve side heaters 100A and 100B.

To solve such a problem, it may be very useful to reduce the set temperature of each heater so as to allow the actual temperature of the sealing member 56 to be lower than a temperature at which the amount of the gas permeating the sealing member 56 increases. Further, to suppress a temperature difference between the chamber sidewall adjacent to the gate valve 90 and the opposite chamber sidewall adjacent to the observation window 97, it may be also very useful to determine the set temperature of the chamber sidewall adjacent to the observation window 97 to be slightly higher than the set temperature of the chamber sidewall adjacent to the gate valve 90.

<Evaluation of the Method of the Present Disclosure>

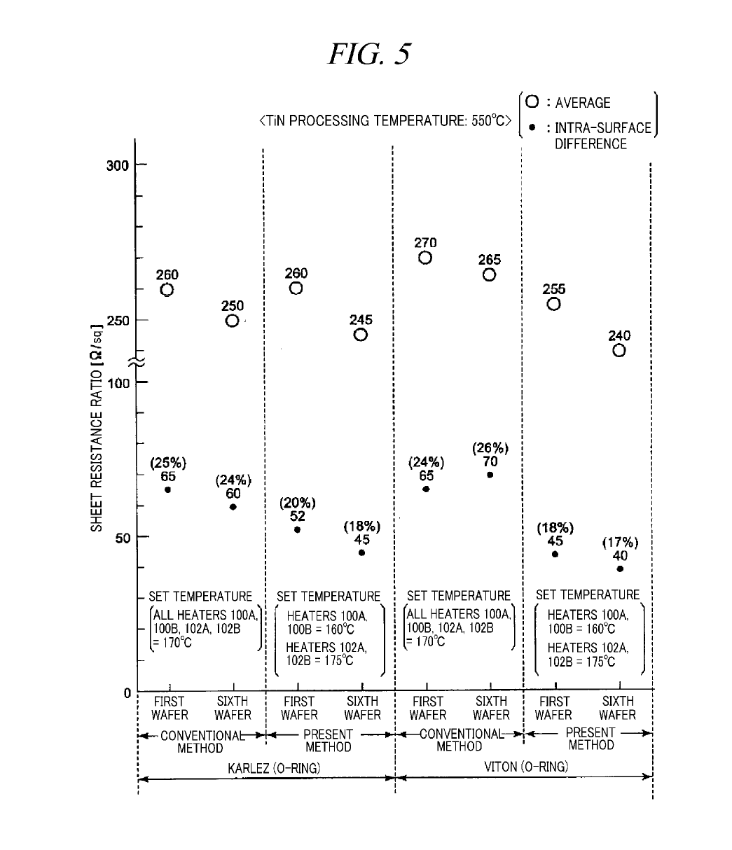

The above-described method in accordance with the embodiment of the present disclosure was performed, and the result was evaluated. The evaluation result will be explained. FIG. 5 is a graph showing sheet resistance states of TiN films (thin films) formed on semiconductor wafers by a conventional method and the present disclosure method.

Here, the TiN films were formed by CVD while using a TiCl₄ gas and a NH₃ gas in the same method as described above. A processing temperature, i.e., a wafer temperature was about 550° C., and a processing pressure was about 666 Pa. The evaluation was made for each of cases in which Karlez (registered trademark) and Viton (registered trademark) were used as the sealing member 56, i.e., an O-ring between the cover 44 and the chamber main body 46.

In the conventional method, the set temperatures of the gate valve side heaters 100A and 100B and the outer side heaters 102A and 102B were all about 170° C.

In the present disclosure method, however, the set temperatures of the gate valve side heaters 100A and 100B were about 160° C., while the set temperatures of the outer side heaters 102A and 102B were about 175° C., slightly higher than 160° C.

Further, film forming processes of the TiN films were performed on 6 sheets of wafers in each case. Among the six wafers, sheet resistances of thin films on a first wafer and a sixth wafer were measured. Then, an average value and an intra-surface difference (difference between a maximum value and a minimum value) of the sheet resistances were respectively calculated. In FIG. 5, an intra-surface difference of the sheet resistances is expressed by using its ratio (percentage) to the average value of the sheet resistances (i.e., intra-surface difference/average value).

As can be clearly seen from the graph shown in FIG. 5, when Karlez is used as the sealing member 56 in case of the conventional method, average values of sheet resistances on a first wafer and a sixth wafer are about 260Ω/sq (ohms per square) and about 250Ω/sq, respectively, and intra-surface differences of the sheet resistances are about 65Ω/sq and about 60Ω/sq, respectively. Here, the ratios of the intra-surface differences of the sheet resistances to the average values of the sheet resistances are about 25% and about 24%, respectively. That is, non-uniformity of the sheet resistances is relatively high, and intra-surface uniformity of the sheet resistances is not good.

In case of the present disclosure method, however, average values of sheet resistances on a first wafer and a sixth wafer are about 260Ω/sq and about 245Ω/sq, respectively, and intra-surface differences of the sheet resistances are about 52Ω/sq and about 45Ω/sq, respectively. Here, the ratios of the intra-surface differences of the sheet resistances to the average values of the sheet resistances are about 20% and about 18%, respectively. That is, as compared to the conventional method, non-uniformity of the sheet resistances is relatively low, and intra-surface uniformity of the sheet resistances is improved.

Further, when Viton is used as the sealing member 56 in case of the conventional method, average values of sheet resistances on a first wafer and a sixth wafer are about 270Ω/sq and about 265Ω/sq, respectively, and intra-surface differences of the sheet resistances are about 65Ω/sq and about 70Ω/sq, respectively. Here, the ratios of the intra-surface differences of the sheet resistances to the average values of the sheet resistances are about 24% and about 26%, respectively. That is, non-uniformity of the sheet resistances is relatively high, and intra-surface uniformity of the sheet resistances is not good.

In case of the present disclosure method, however, average values of sheet resistances on a first wafer and a sixth wafer are about 255Ω/sq and about 240Ω/sq, respectively, and intra-surface differences of the sheet resistances are about 45Ω/sq and about 40Ω/sq, respectively. Here, the ratios of the intra-surface differences of the sheet resistances to the average values of the sheet resistances are about 18% and about 17%, respectively. That is, as compared to the conventional method, non-uniformity of the sheet resistances is relatively low, and intra-surface uniformity of the sheet resistances is improved.

As described above, in accordance with the present disclosure method, the intra-surface difference of the sheet resistances can be reduced to about 52Ω/sq or less in the formation of the TiN film. Further, the intra-surface difference can be reduced to about 20% or less of the average value of the sheet resistances. That is to say, the set temperature of the gate valve side heaters 100A and 100B and the set temperature of the outer side heaters 102A and 102B can be respectively determined so as to allow the intra-surface difference of the sheet resistances to become about 52Ω/sq or less, or to allow the intra-surface difference of the sheet resistances to be about 20% or less of the average value of the sheet resistances.

The above-specified set temperatures of 160° C. and 175° C. are nothing more than examples. The set temperatures are not particularly limited as long as the sidewall temperature of the processing chamber 42 is equal to or higher than the sublimation temperature of the reaction by-product and below the temperature at which the amount of the gas permeating the sealing member 56 increases.

Further, although the TiN film has been illustrated as an example target film to be formed, the kind of the target film is not limited thereto. For example, the present disclosure can also be applied to the formation of a metal film such as a Ti film, a Ta (tantalum) film or a W (tungsten) film; a metal-containing film such as a metal nitride film or a metal oxide film of Ti, Ta or W; and so forth.

Furthermore, although the description has been provided for the case of using the heater 70 embedded in the mounting table 68 as the processing target object heating unit, the present disclosure is not limited to this configuration. For example, the present disclosure can also be applied to a so-called lamp heater type processing apparatus in which a thin mounting table 68 is provided and a heater lamp is provided as the processing target object heating unit below the mounting table 68 so as to heat the semiconductor wafer indirectly.

Moreover, the present disclosure can also be applied to a processing apparatus that uses, besides the processing target object heating unit, a plasma generation unit configured to generate plasma within the processing space S by using a high frequency power or a microwave power.

In addition, the above embodiment has been described for the case of setting the sidewall temperature of the processing chamber to be equal to or higher than the temperature (sublimation temperature) capable of preventing adhesion of the reaction by-product. However, when a source gas is generated by vaporizing a solid source or a liquid source, the sidewall temperature of the processing chamber may be set to be equal to or higher than a temperature (condensation temperature) at which the source gas would be re-liquefied or re-solidified and condensed and adhered to the chamber sidewall.

Moreover, in the above-described embodiment, the heaters 100A, 100B and 102A and 102B are divided into two separate systems, i.e., the gate valve side system and the outer (observation window) side system, respectively, and controlled. However, the present disclosure is not limited to this configuration. For example, the four heaters may be individually controlled.

Further, although the semiconductor wafer has been illustrated as the processing target object, the processing target object is not limited thereto. For example, the present disclosure is also applicable to a glass substrate, an LCD substrate, a ceramic substrate, or the like.

Furthermore, although the above embodiment has been described for the case of using the single-wafer processing apparatus, it will be apparent to those skilled in the art that the present disclosure is also applicable to a batch type apparatus. Still further, although the film forming process has been illustrated, the present disclosure can also be applied to a nitrification process, an oxidation process, a diffusion process, a quality modification process, an etching process, and the like.

What is claimed is:

1. A heat treatment apparatus comprising:
a processing chamber having a gate valve at a sidewall and a cover at a ceiling via a sealing member, the gate valve being configured to be opened and closed so as to load and unload a processing target object and the cover being configured to be opened and closed;
a mounting table provided within the processing chamber and configured to mount the processing target object;
a gas introduction unit configured to introduce a gas into the processing chamber;
an exhaust unit configured to exhaust an atmosphere gas in the processing chamber;
a processing target object heating unit configured to heat the processing target object;
a gate valve heating unit provided at the gate valve;
a processing chamber heating unit provided at a sidewall of the processing chamber; and
a temperature controller that controls a set temperature for the sidewall of the processing chamber adjacent to the gate valve to be lower than a set temperature for an opposite sidewall of the processing chamber from the gate valve by way of controlling the processing chamber heating unit,
wherein the two set temperatures are set to be equal to or higher than a sublimation temperature of a reaction by-product generated by a heat treatment performed on the processing target object, or equal to or higher than a condensation temperature of the gas, and
the two set temperatures are also set to be equal to or lower than a temperature at which an amount of a gas permeating the sealing member increases.

2. The heat treatment apparatus of claim 1, wherein the processing chamber heating unit includes:
a pair of gate valve side heaters provided at the sidewall of the processing chamber adjacent to the gate valve and arranged apart from each other at a preset distance;
a pair of outer side heaters provided at the opposite sidewall of the processing chamber from the gate valve and arranged apart from each other at a preset distance.

3. The heat treatment apparatus of claim 2, wherein a gate valve side temperature measuring unit is provided in the vicinity of the gate valve side heaters to measure a temperature of the gate valve side heaters, and
an outer side temperature measuring unit is provided in the vicinity of the outer side heaters to measure a temperature of the outer side heaters.

4. The heat treatment apparatus of claim 1, wherein a difference between the two set temperatures is in a range of about 5° C. to about 30° C.

5. The heat treatment apparatus of claim 1, wherein the heat treatment is a film forming process for forming a thin film, and the two set temperatures are determined to allow an intra-surface difference of sheet resistances of the thin film to be equal to or smaller than about 20% of an average value of the sheet resistances.

6. The heat treatment apparatus of claim 1, wherein the sealing member is made of a fluoroelastomer-based material.

7. A method for controlling a heat treatment apparatus including a processing chamber having a gate valve at a sidewall and a cover at a ceiling via a sealing member, the gate valve being configured to be opened and closed so as to load and unload a processing target object and the cover being configured to be opened and closed; a mounting table installed within the processing chamber and configured to mount the processing target object; a gas introduction unit configured to introduce a gas into the processing chamber; an exhaust unit configured to exhaust an atmosphere gas in the processing chamber; a processing target object heating unit configured to heat the processing target object; a gate valve heating unit provided at the gate valve; a processing chamber heating unit provided at a sidewall of the processing chamber; and a temperature controller that controls the processing chamber heating unit, the method comprising:
increasing a set temperature for the sidewall of the processing chamber adjacent to the gate valve lower than a set temperature for an opposite sidewall of the processing chamber from the gate valve by using the temperature controller,
wherein the two set temperatures are set to be equal to or higher than a sublimation temperature of a reaction by-product generated by a heat treatment performed on the processing target object, or equal to or higher than a condensation temperature of the gas, and
the two set temperatures are also set to be equal to or lower than a temperature at which an amount of a gas permeating the sealing member increases.

8. The control method of claim 7, wherein a difference between the two set temperatures is in a range of about 5° C. to about 30° C.

9. The control method of claim 7, wherein the heat treatment is a film forming process for forming a thin film, and the two set temperatures are determined to allow an intra-surface difference of sheet resistances of the thin film to be equal to or smaller than about 20% of an average value of the sheet resistances.

10. A storage medium storing therein a computer program for executing a method for controlling a heat treatment apparatus as claimed in claim 7.
